(19) United States
(12) Patent Application Publication
(10) Pub. No.: US 2009/0125765 A1
(43) Pub. Date: May 14, 2009

(54) Apparatus for Certifying Hardware Abstraction Layer in Mobile Terminal and Method Thereof

(75) Inventors: Sang-Yun Lee, Daejon (KR); Hwan-Gu Lee, Daejon (KR); Woo-Sik Kim, Incheon (KR); Jae-Ho Lee, Daejon (KR); Sun-Ja Kim, Daejeon (KR); Heung-Nam Kim, Daejon (KR)

Correspondence Address: RABIN & Berdo, PC, 1101 14TH STREET, NW, SUITE 500, WASHINGTON, DC, 20005, US

(73) Assignee: Electronics and Telecommunications Research Institute, Daejon (KR)

(21) Appl. No.: 11/720,324

(22) PCT Filed: Nov. 24, 2005
(86) PCT No.: PCT/KR05/03978

§ 371 Date: May 25, 2007

(30) Foreign Application Priority Data
Nov. 25, 2004 (KR) 10-2004-0097690

(51) Int. Cl. G01R 31/28

(52) U.S. Cl. 714/724

(57) ABSTRACT

Provided is an apparatus and method for certifying a hardware abstraction layer in a mobile terminal. The apparatus includes: a communication unit for receiving a predetermined test case from an external host certifying system and transmitting a test result of performing the received test cast to the host certifying system; an event receiver for receiving a test result of performing an event type test case from a hardware abstraction layer; and a controller for controlling the hardware abstraction layer to perform the test case received through the communication unit, and receiving the test result of performing the received test case received from the event receiver or the hardware abstraction layer and transmitting the received test result to the host certifying system.

### TECHNICAL FIELD

The present invention relates to an apparatus for certifying a hardware abstraction layer in a mobile terminal and a method thereof; and more particularly, to an apparatus for certifying an operating state of a hardware abstraction layer that performs operations for a mobile standard platform, i.e., wireless internet platform for interoperability (WIPI), and an interface function to a basic software in a mobile terminal, and a method thereof.

### BACKGROUND ART

A mobile terminal denotes a portable terminal employing a mobile standard platform and capable of processing audio, text and video data, such as a personal communication service (PCS) terminal, a personal digital assistant (PDA), a smart phone, a next generation mobile communication terminal capable of processing data in IMT-2000 standard and a wireless local area network (LAN) terminal.

The mobile standard platform denotes a wireless Internet standardization platform which is created by a Korea Wireless Internet Standard Forum (KWISF) and employed by Telecommunications Technology Association (TTA).

Mobile terminals generally employs a hardware abstraction layer which is a lowest layer of a platform in order to employ a mobile standard platform to allow the mobile terminal to have various hardware and basic software environment. That is, a mobile standard platform can be easily implanted into a mobile terminal by embedding the hardware abstraction layer in a mobile terminal by a manufacturer.

The mobile terminals having various hardware structures and software environments include a platform certifying agent, i.e., toolkit, to certify operating states of the mobile standard platform in the mobile terminals.

Hereinafter, a conventional platform certifying agent will be described with reference to FIG. 1 in detail.

FIG. 1 is a block diagram of a conventional platform certifying agent. As shown in FIG. 1, the conventional platform certifying agent certifies entire functions of a mobile standard platform 14 in response to a remote certifying request from a host certifying system 10. However, the conventional platform certifying agent does not certify functions of an application program interface (API) 11, an engine 12 and a hardware abstraction layer 13 when errors are generated in the mobile terminal having the conventional platform certifying agent. That is, the conventional platform certifying agent certifies only functions of the mobile standard platform.

The mobile standard platform 14 includes the application program interface 11 for providing an interface to the application programs, the engine 12 for executing a mobile standard platform and the hardware abstraction layer 13 for performing operations to interface between the mobile standard platform and the basic software.

Therefore, the conventional platform certifying agent cannot identify a layer having the error among entire mobile standard platform when error is generated because the conventional platform certifying agent certifies only functions of the mobile standard platform.

Furthermore, it is difficult to debug because the conventional platform certifying agent cannot find a layer that generates an error.

### DISCLOSURE

### Technical Problem

It is, therefore, an object of the present invention to provide an apparatus for certifying operating states of a hardware abstraction layer that performs operations to interface between a mobile standard platform and a basic software to narrow a range of layers generating an error to a predetermined layer.

### Technical Solution

In accordance with one aspect of the present invention, there is provided an apparatus for certifying a hardware abstraction layer in a mobile terminal, the apparatus including: a communication unit for receiving a predetermined test case from an external host certifying system and transmitting a test result of performing the received test cast to the host certifying system; an event receiver for receiving a test result of performing an event type test case from a hardware abstraction layer; and a controller for controlling the hardware abstraction layer to perform the test case received through the communication unit, and receiving the test result of performing the received test case received from the event receiver or the hardware abstraction layer and transmitting the received test result to the host certifying system.

In accordance with another aspect of the present invention, there is provided a method for certifying a hardware abstraction layer in a mobile terminal, the method including the steps of: receiving a test case from an external certifying system; controlling a hardware abstraction layer to perform the received test case; transferring a result of performing the test case from the hardware abstraction layer; and transmitting the received result of performing the test case to the host certifying system.

### Advantageous Effects

An apparatus for certifying a hardware abstraction layer according to the present invention narrows down a range of layers generating an error to a predetermined layer by certifying operating states of a hardware abstraction layer that performs operations to interface between a mobile standard platform and a basic software.

### DESCRIPTION OF DRAWINGS

The above and other objects and features of the present invention will become apparent from the following description of the preferred embodiments given in conjunction with the accompanying drawings, in which:

FIG. 1 is a block diagram showing a conventional platform certifying agent;

FIG. 2 is a block diagram illustrating a hardware abstraction layer certifying agent in accordance with a preferred embodiment of the present invention;

FIG. 3 is a block diagram depicting an apparatus for certifying a hardware abstraction layer in accordance with a preferred embodiment of the present invention; and

FIG. 4 is a flowchart showing a method of certifying a hardware abstraction layer in accordance with a preferred embodiment of the present invention.

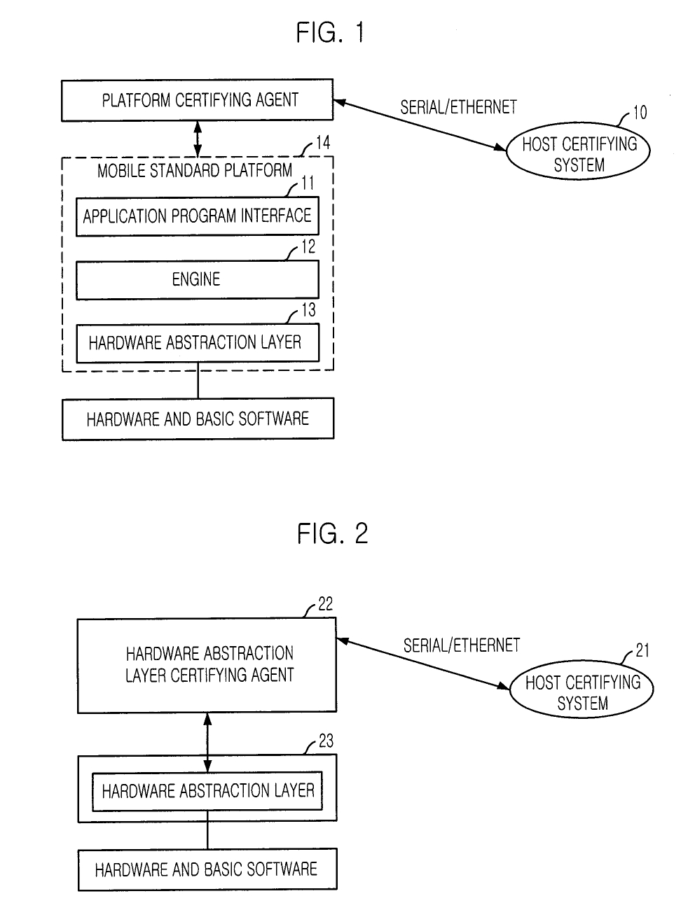

### BEST MODE FOR THE INVENTION

Other objects and aspects of the invention will become apparent from the following description of the embodiments with reference to the accompanying drawings, which is set forth hereinafter.

FIG. 2 is a block diagram illustrating a hardware abstraction layer certifying agent in accordance with a preferred embodiment of the present invention.

As shown in FIG. 2, the hardware abstraction layer certifying agent according to the present invention receives a remote certifying request with predetermined test cases from a host certifying system 21 through a serial/Ethernet/universal serial bus (USB), and certifies functions of the hardware abstraction layer 23 that performs operations to interface between a mobile standard platform and basic software in a mobile terminal according to the received request and test cases.

The hardware abstraction layer 23 performs the test cases in response to a controller 34 of the hardware abstraction layer certifying agent, and transfers the result of the test cases to the controller 34. The result is transmitted to an event receiver 32 of the hardware abstraction layer certifying agent if the result is an event type.

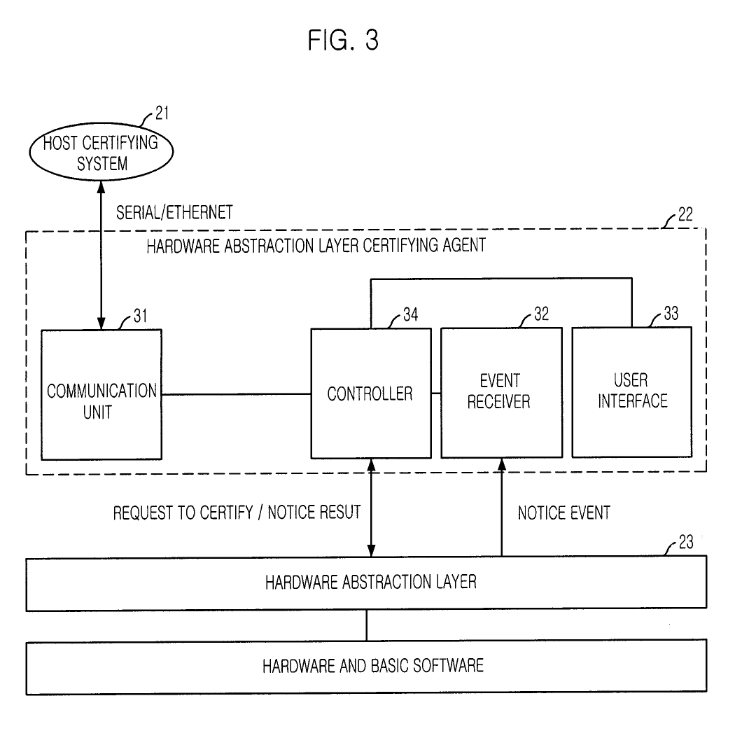

FIG. 3 is a block diagram depicting an apparatus for certifying a hardware abstraction layer in accordance with a preferred embodiment of the present invention.

As shown in FIG. 3, the apparatus for certifying a hardware abstraction layer according to the present invention includes: a communication unit 31 for receiving predetermined test cases created according to the hardware specification from a host certifying system 21 and transmitting results of the received test cases and other test cases received through a user interface 33 to the host certifying system 21; an event receiver 32 for receiving an event type result of the test cases from the hardware abstraction layer 23; a user interface unit 33 for receiving a test case that requires a user's verification such as an input/output of data on a display; and a controller 34 for receiving test cases from the host certifying system 21 through the communication unit 31 or receiving test cases from the user through the user interface unit 33, controlling the hardware abstraction layer 23 to perform the received test cases and transferring the result of the test cases received from the hardware abstraction layer 23 or the event receiver 32 to the host certifying system 21 through the communication unit 31.

In the present invention, the user interface unit 33 is a supplementary unit.

The test cases received from the user interface unit 33 includes a predetermined value.

The host certifying system stores entire test cases to test all functions of the hardware abstraction layer 23. The host certifying system also stores the result of performing the test cases, received from the hardware abstraction layer certifying agent 22 through the communication unit 31.

The host certifying system selects predetermined test cases from entire test cases by considering the hardware specification of a mobile terminal having the hardware abstraction layer certifying agent, and transmits the selected test cases to the communication unit 31 of the hardware abstraction layer certifying agent 22.

The event receiver 32 receives the event from the hardware abstraction layer 23 when the result of performing the case tests is an event type and stores the received event in an event queue (not shown).

The controller 34 receives the test cases from the host certifying system 21 through the communication unit 31 or receives other test cases from the user through the user interface 33. The controller 34 analyzes the types of the received test cases and may predict the receiving of event from the hardware abstraction layer 23.

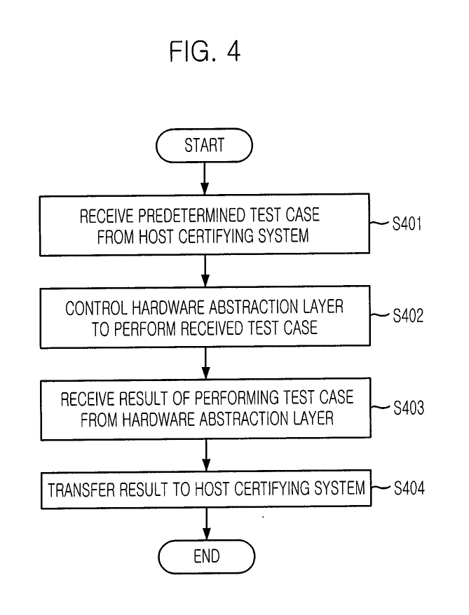

FIG. 4 is a flowchart showing a method of certifying a hardware abstraction layer in accordance with a preferred embodiment of the present invention.

As shown in FIG. 4, the test case is received from the host certifying system 21 through the communication unit 31 or other test cases from a user through the user interface 22 at step S401. Herein, the controller analyzes the type of the received test case and estimates the receiving of the event from the hardware abstraction layer 23.

Then, the hardware abstraction layer 23 is controlled to perform the received test cases at step S402.

After performing the test case, the result of performing the test case is received at step S403. Herein, if the type of the test result is an event type, the event receiver 32 receives the test result. Then, the event receiver 32 stored the received test result in the event queue.

After receiving, the test result is transferred to the host certifying system 21 through the communication unit 31 at step S404.

As described above, the hardware abstraction layer certifying agent according to the present invention certifies functions of hardware abstraction layer 23.

While the present invention has been described with respect to certain preferred embodiments, it will be apparent to those skilled in the art that various changes and modifications may be made without departing from the scope of the invention as defined in the following claims.

What is claimed is:

1. An apparatus for certifying a hardware abstraction layer in a mobile terminal, the apparatus comprising:
communication means for receiving a predetermined test case from an external host certifying system and transmitting a test result of performing the received test cast to the host certifying system;
event receiving means for receiving an event type test result from a hardware abstraction layer; and
controlling means for controlling the hardware abstraction layer to perform the test case received through the communication means, and receiving the test result of performing the received test case received from the event receiving means or the hardware abstraction layer and transmitting the received test result to the host certifying system.

2. The apparatus as recited in claim 1, further comprising interfacing means for receiving a test case that requires a user's confirmation such as an input/output of data on a display.

3. The apparatus as recited in claim 1, wherein the controlling means predicts a receiving of event from a hardware abstraction layer by analyzing a type of the received test case.

4. A method for certifying a hardware abstraction layer in a mobile terminal, the method comprising the steps of:
receiving a test case from an external certifying system;
controlling a hardware abstraction layer to perform the received test case;
transferring a result of performing the test case from the hardware abstraction layer; and
transmitting the received result of performing the test case to the host certifying system.

5. The method as recited in claim 4, further comprising the step of predicting a receiving of an event from the hardware abstraction layer by analyzing a type of the received test case.

6. The method as recited in claim 4, wherein in the step of receiving the test result, the received test result is stored in an event queue through an event receiving means if the received test result is a type of event.
